(19) United States
(12) Patent Application Publication
(10) Pub. No.: US 2009/0046113 A1
(43) Pub. Date: Feb. 19, 2009

(54) Uneven streaks evaluation device, uneven streaks evaluation method, storage medium, and color filter manufacturing method

(75) Inventors: Takeshi Murakami, Nara (JP); Eiji Yamada, Nara (JP)

Correspondence Address: EDWARDS ANGELL PALMER & DODGE LLP, P.O. BOX 55874, BOSTON, MA, 02205, US

(73) Assignee: Sharp Kabushiki Kaisha, Osaka (JP)

(21) Appl. No.: 12/220,852

(22) Filed: Jul. 29, 2008

(30) Foreign Application Priority Data
Jul. 31, 2007 (JP) 199978/2007

(51) Int. Cl. G09G 5/02; G06K 9/40; G03F 1/00

(52) U.S. Cl. 345/690; 382/260; 430/7

(57) ABSTRACT

A present uneven streaks evaluation device includes an evaluation data generation section for generating evaluation data, serving as an index for evaluating cyclic uneven streaks occurring on an evaluation target surface, in accordance with image data obtained by imaging the evaluation target surface to which light is emitted, wherein a one-dimensional projection processing section carries out a one-dimensional projection process with respect to light distribution included in the image data so that a projection direction is a direction including a vector of a direction in which uneven streaks occur, a power spectrum calculation section calculates a power spectrum in accordance with the light distribution having been subjected to the one-dimensional projection process, an integration processing section calculates an interval integral value of a preset cycle in accordance with the calculated power spectrum, and a noise component removing section removes a noise component included in the calculated interval integral value.

This Nonprovisional application claims priority under U.S.C. § 119(a) on Patent Application No. 199978/2007 filed in Japan on Jul. 31, 2007, the entire contents of which are hereby incorporated by reference.

### FIELD OF THE INVENTION

The present invention relates to an uneven streaks evaluation device for evaluating an appearance tendency of uneven streaks occurring at a specific cycle (or at a specific period) in accordance with image data obtained by imaging an evaluation target.

### BACKGROUND OF THE INVENTION

Recently, display devices such as televisions and monitors have been made thinner and larger. Also such demand has been increasing. With such trend, a higher quality display performance has been required.

Among components constituting a display device, a color filter for carrying out a color display is an important component which greatly influences display quality. Thus, also quality of the color filter has been required to be higher.

Further, cost of the color filter occupies a large part of entire manufacturing cost. Thus, it has been required to improve an yield of the color filter so as to reduce the manufacturing cost of each display device.

In these days, a color filter formation method based on an inkjet process attracts attentions. According to the formation method, nozzles of an inkjet head respectively eject R (red), G (green), and B (blue) inks, onto pixels, thereby forming a color filter. The inkjet process is characterized in that the number of steps required is small and unnecessary use of ink is suppressed, so that it is possible to realize a shorter process and lower cost.

However, in case of forming a color filter in accordance with the inkjet process, particularly uneven streaks are likely to occur. This may result in lower display quality and production of an inferior product. Also, uneven streaks occur at a specific cycle in this case, so that it is important to evaluate the uneven streaks occurring a specific cycle.

A technique for detecting uneven streaks is disclosed by Patent Document 1 (Japanese Unexamined Patent Publication Tokukai 2005-77181 (Publication date: Mar. 24, 2005)) for example.

Patent Document 1 discloses an arrangement in which: vertical luminance data and horizontal luminance data of an obtained image are respectively accumulated as accumulated data sets, and a moving average of each accumulated data set is calculated so as to obtain an accumulated moving average data set, and a difference between the accumulated data set and the accumulated moving average data set is referred to so as to detect uneven streaks occurring at a specific cycle.

Although the technique of Patent Document 1 allows for detection of cyclic uneven streaks, the technique raises such problem that it is impossible to evaluate an appearance tendency of the uneven streaks, particularly, it is impossible to evaluate an appearance tendency of uneven streaks occurring at a preset specific cycle.

### SUMMARY OF THE INVENTION

An object of the present invention is to provide an uneven streaks evaluation device which can appropriately evaluate an appearance tendency of uneven streaks occurring at a specific cycle (or at a specific period) in accordance with image data.

In order to achieve the foregoing object, an uneven streaks evaluation device according to the present invention comprises evaluation data generation means for generating evaluation data, serving as an index for evaluating cyclic uneven streaks which occur on an evaluation target surface of a display member, in accordance with image data obtained by imaging the evaluation target surface to which light is emitted, wherein the evaluation data generation means includes: one-dimensional projection processing means for carrying out a one-dimensional projection process with respect to light distribution included in the image data; power spectrum calculation means for calculating a power spectrum in accordance with the light distribution having been subjected to the one-dimensional projection process carried out by the one-dimensional projection processing means; integration means for calculating an interval integral value of a preset cycle in accordance with the power spectrum calculated by the power spectrum calculation means; and noise component removing means for removing a noise component included in the interval integral value calculated by the integration means.

Further, in order to solve the foregoing problems, a method of the present invention for evaluating uneven streaks is a method for evaluating cyclic uneven streaks occurring on an evaluation target surface of a display member, in accordance with image data obtained by imaging the evaluation target surface to which light is emitted, said method comprising: a first step of carrying out a one-dimensional projection process with respect to light distribution information included in the image data so that a projection direction is a direction including a vector of a direction in which uneven streaks occur; a second step of calculating a power spectrum in accordance with the light distribution having been subjected to the one-dimensional projection process in the first step; a third step of calculating an interval integral value of a preset cycle in accordance with the power spectrum calculated in the second step; and a fourth step of removing a noise component included in the interval integral value calculated in the third step.

According to the foregoing arrangement, the one-dimensional projection process is carried out with respect to the light distribution information included in the image data obtained by imaging the evaluation target surface, so that it is possible to specify a direction in which uneven streaks occur on the evaluation target surface. Further, the power spectrum is calculated in accordance with the light distribution having been subjected to the one-dimensional projection process, so that it is possible to express an appearance intensity of cyclic uneven streaks. Further, the interval integral value of a preset cycle is calculated in accordance with the power spectrum, so that it is possible to calculate an integral value of the appearance intensity of uneven streaks of a specific cycle component. This makes it possible to calculate an occurrence direction (appearance position), an occurrence intensity (appearance intensity), and the like of uneven streaks occurring at a specific cycle on the evaluation target surface, so that it is possible to evaluate an appearance tendency (appearance position, appearance intensity) of uneven streaks occurring at a specific cycle.

Moreover, the noise component included in the integral value is removed, so that it is possible to accurately evaluate appearance tendencies of uneven streaks occurring at specific cycles even when the uneven streaks on the evaluation target surface occur at plural kinds of cycles.

Further, the uneven streaks evaluation device may be arranged so as to further comprise area dividing means for dividing the image data into a plurality of areas, wherein the evaluation data generation means generates evaluation data for the image data so that the evaluation data corresponds to each of the areas obtained through division carried out by the area dividing means.

Thus, not the entire image data but image data of each area can be evaluated, so that it is possible to improve evaluation accuracy. For example, in case where uneven streaks are caused by abnormal plotting, the uneven streaks occur in a range of the plotting unit, so that it is possible to improve evaluation accuracy by corresponding each area of the image data to a size of the plotting unit.

Further, a size of each of the areas obtained through division carried out by the area dividing means is arbitrary, and the size is suitably set according to an appearance tendency of uneven streaks on the evaluation target.

At this time, it may be so arranged that the area dividing means divides the image data into areas so as to correspond to a preset range of uneven streaks.

Further, it may be so arranged that the area dividing means causes the areas to overlap with each other so that a range of uneven streaks occurring at a specific cycle is positioned in the same area in dividing the image data into areas.

By causing the areas to overlap with each other in this manner, it is possible to thoroughly evaluate the evaluation target areas of the evaluation target, thereby evaluating uneven streaks with higher accuracy.

The uneven streaks evaluation device may be arranged so as to further comprise evaluation value calculation means for calculating an evaluation value, which is indicative of an appearance position and an appearance intensity of uneven streaks occurring at a specific cycle in the image data, in accordance with the evaluation data, wherein the evaluation value calculation means calculates the evaluation value in accordance with the evaluation data generated by the evaluation data generation means so that the evaluation data corresponds to each of the areas.

This makes it possible to find out a position and a degree of uneven streaks occurring on the image data.

Further, it may be so arranged that the evaluation value calculation means calculates evaluation data in the same direction as a direction in which uneven streaks occur is extracted from the evaluation data having been generated, and an evaluation value of the uneven streaks is calculated in accordance with the evaluation data having been extracted.

This makes it possible to more accurately evaluate uneven streaks occurring in a straight line manner in a vertical direction or a horizontal direction. This arrangement is suitable for evaluation of a product, such as a color filter, in which uneven streaks are likely to occur in a straight line manner.

At this time, it may be so arranged that the evaluation value calculation means calculates an arithmetic average value of the evaluation data, having been extracted, as an evaluation value of uneven streaks.

Further, it may be so arranged that the evaluation value calculation means calculates a trim average value of the evaluation data, having been extracted, as an evaluation value of uneven streaks.

Further, it may be so arranged that the evaluation value calculation means calculates a median value of the evaluation data, having been extracted, as an evaluation value of uneven streaks.

Further, it may be so arranged that the evaluation value calculation means calculates an rms (root mean square) value of the evaluation data, having been extracted, as an evaluation value of uneven streaks.

Each of the evaluation calculation means allows an evaluation value of uneven streaks to be appropriately evaluated, and it is preferable to adopt such evaluation value calculation means that: a portion actually having uneven streaks and a portion free from any uneven streaks are evaluated, and calculation is carried out with respect to the two portions (classes) so that a ratio of intraclass dispersion and interclass dispersion is maximum. That is, as the ratio is greater, the class having uneven streaks and the class free from any uneven streaks are separated further away from each other. Thus, it is possible to appropriately evaluate uneven streaks.

It may be so arranged that the one-dimensional projection processing means carries out the one-dimensional projection process with respect to the light distribution information so that a projection direction is the same as the direction in which uneven streaks occur.

This makes it possible to suppress irregularities of luminance values included in the image data, thereby improving an S/N ratio.

It may be so arranged that a range of the interval integral value calculated by the integration means includes a cycle of uneven streaks to be evaluated.

Further, it may be so arranged that a range of the interval integral value calculated by the integration means includes a cycle having a certain intensity.

In this case, it is possible to realize the following operation: An interval integral range is preset when a cycle of uneven streaks to be evaluated is determined, and uneven streaks intensely occurring at a certain cycle is evaluated in accordance with the power spectrum calculation result or the like.

It may be so arranged that the integration means calculates a power spectrum density in accordance with the power spectrum and carries out interval integration with respect to a result of the calculation at a preset cycle so as to calculate the interval integral value.

It may be so arranged that the integration means calculates a power spectrum density in accordance with the power spectrum and calculates a square root of a value, obtained by carrying out interval integration with respect to a result of that calculation at a preset cycle, so as to calculate the interval integral value.

This makes it possible to quantitatively evaluate the evaluation result.

It may be so arranged that the noise component removed by the noise component removing means is a cycle component different from a cycle of uneven streaks to be evaluated.

It may be so arranged that the noise component includes a cycle component having a certain intensity.

This makes it possible to realize the following evaluation: A cycle interval is preset when an appearance cycle of uneven streaks is determined, and a cycle component which is included in the image data and whose intensity is not less than a certain value is regarded as a noise component when the appearance cycle is not determined.

Further, the uneven streaks evaluation device may be arranged so as to further comprise evaluation value calculation means for calculating an evaluation value, which is indicative of an appearance position and an appearance intensity of uneven streaks occurring at a specific cycle in the image data, in accordance with the evaluation data, wherein the evaluation data generation means generates evaluation data sets respectively in accordance with a plurality of image data sets respectively obtained by imaging the evaluation target surface of the same display member from different directions, and the evaluation calculation means extracts, from the evaluation data having been generated by the evaluation data generation means, evaluation data generated in accordance with an image data set obtained from a direction which allows less influence of the noise component, and calculates the evaluation value in accordance with the evaluation data having been extracted.

Thus, it is possible to carry out the evaluation with higher accuracy by adopting an evaluation result of the image data obtained from a direction which allows less generation of a noise component, so that it is possible to evaluate a direction which allows occurrence of uneven streaks having high intensity.

At this time, it is preferable that the directions in which the image data sets are obtained at least include: an oblique direction in which a characteristic of uneven streaks are capable of being observed; and a direction opposite to the oblique direction.

The uneven streaks evaluation device is arranged so that the display member is a color filter.

This makes it possible to accurately evaluate an appearance tendency of uneven streaks occurring at a specific cycle on the color filter surface.

In order to solve the foregoing problems, a method of the present invention for manufacturing a color filter is a method for manufacturing a color filter by using a color filter manufacturing device, said method comprising an uneven streaks evaluation step of carrying out the aforementioned method for evaluating cyclic uneven streaks, wherein the evaluation value which has been obtained in the uneven streaks evaluation step and is indicative of an appearance tendency, such as an appearance range, an intensity, and a direction, of unevenness streaks occurrence is outputted to the color filter manufacturing device as feedback information.

Thus, information of an appearance tendency of uneven streaks occurring at a specific cycle is outputted to the color filter manufacturing device as feedback information, so that it is possible to appropriately solve a trouble (occurrence of uneven streaks) occurring in the color filter plotting step. As a result, it is possible to improve the display quality of the color filter.

Additional objects, features, and strengths of the present invention will be made clear by the description below. Further, the advantages of the present invention will be evident from the following explanation in reference to the drawings.

### BRIEF DESCRIPTION OF THE DRAWINGS

FIG. 1, showing an embodiment, is a block diagram illustrating an essential configuration of an evaluation device.

FIG. 2 is a block diagram schematically illustrating a specific cycle uneven streaks evaluation system using the evaluation device of FIG. 1.

FIG. 3 is a drawing illustrating a step for manufacturing a color filter which is an evaluation target.

FIG. 4 is a drawing illustrating an image obtained by imaging a color filter with cameras of the specific cycle uneven streaks evaluation system of FIG. 2.

FIG. 5 is a graph illustrating a result of a one-dimensional projection process carried out in accordance with two-dimensional luminance distribution information obtained from the image of FIG. 4.

FIG. 6 is a graph illustrating a result of Fourier transform carried out with respect to data of the graph of FIG. 5.

FIG. 7 is a flowchart illustrating a process flow for evaluating specific cycle uneven streaks with the evaluation device of FIG. 1.

FIG. 8 is a drawing illustrating an example of calculation of a noise intensity.

FIG. 9 is a drawing illustrating an example of a technique for specifying an uneven-streak occurrence point in accordance with the noise intensity calculated in FIG. 8.

FIG. 10 is a drawing illustrating an example of evaluation carried out in case where a color filter substrate, serving as an evaluation target, is imaged from two directions.

FIG. 11 is a drawing illustrating a specific process flow of the specific cycle uneven streaks evaluation system of FIG. 2.

FIG. 12 is a drawing illustrating an example of a process for removing a noise from an image of an uneven streaks cycle 1.

FIG. 13 is a drawing illustrating an example of a process for removing a noise from an image of an uneven streaks cycle 2.

FIG. 14 is a drawing illustrating an example of a process for removing a noise from an image in which the uneven streaks cycle 1 and the uneven streaks cycle 2 exist in a mixed manner.

FIG. 15 is a flowchart illustrating a process flow in manufacturing a color filter substrate.

### DESCRIPTION OF THE EMBODIMENTS

The following will describe an embodiment of the present invention.

Note that, a display member in the present invention refers to a member, used for a video display device, which transmits and/or reflects light.

Further, as an example of the display member, the present embodiment describes a color filter formed by the inkjet process.

Note that, in the following description, the color filter refers to a filter which allows light of specific wavelength to pass therethrough so that the display device can carry out a color display. Further, the following description is based on such assumption that the color filter is formed by ejecting liquid material, in accordance with the inkjet process, onto a glass substrate having a black matrix thereon. Further, a glass substrate having a black matrix and a color filter thereon is referred to as a color filter substrate.

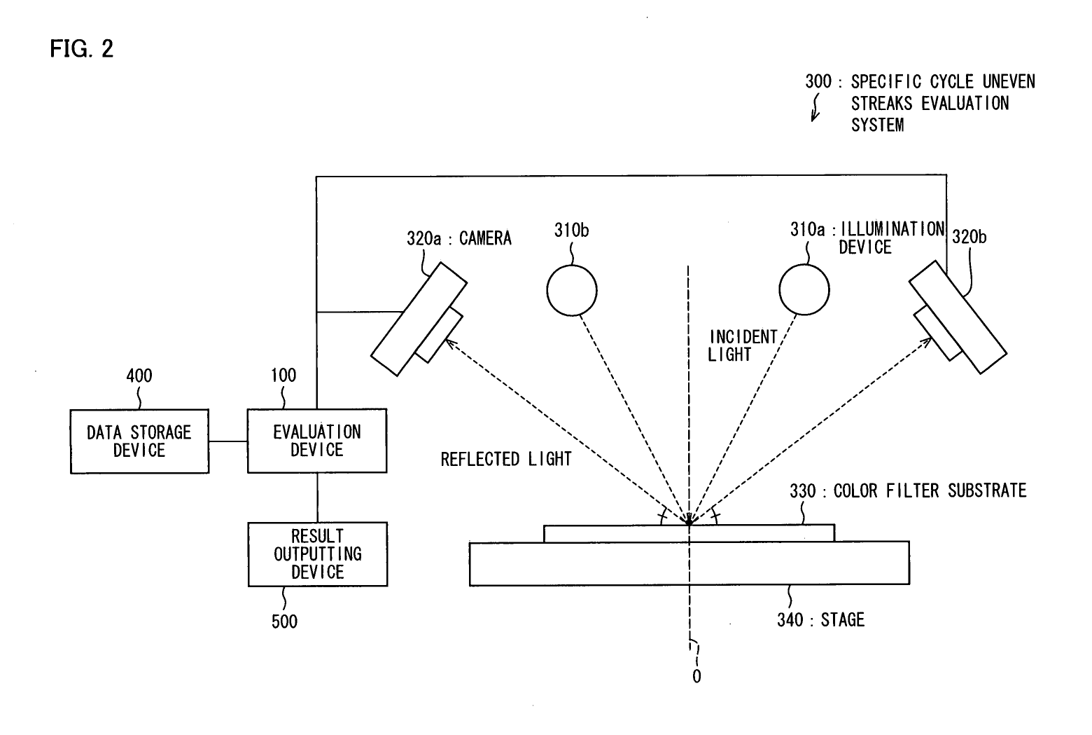

FIG. 2 schematically illustrates a specific cycle (or at a specific period) uneven streaks evaluation system 300 provided with the evaluation device of the present invention.

As illustrated in FIG. 2, the specific cycle uneven streaks evaluation system 300 evaluates uneven streaks occurring at a specific cycle on a surface of a color filter substrate 330 which is an evaluation target, and includes: illumination devices (illumination means) 310a and 310b for emitting light to the surface (color filter formation surface) of the color filter substrate 330; cameras (detection means) 320a and 320b for imaging light reflected by the color filter substrate 330; and a stage 340 on which the color filter substrate 330 is to be placed.

That is, in the specific cycle uneven streaks evaluation system 300 arranged in the foregoing manner, plural (two) cameras 320a and 320b are aimed at the color filter substrate 330, i.e., the evaluation target, at angles different from each other. Image data obtained by the cameras 320a and 320b is temporarily stored in a data storage device 400. An evaluation device 100, as necessary, obtains the image data stored in the data storage device 400. As a result, the evaluation device 100 carries out various kinds of processes such as an injection process and the like with respect to the obtained image data. A result of the evaluation is shown by a result outputting device 500.

Each of the cameras 320a and 320b includes output means for outputting the obtained image to the evaluation device 100. Information outputted from each of the cameras 302a and 302b is image information including luminance distribution information on the surface of the color filter substrate 330. The luminance distribution information indicates distribution of luminance values of each predetermined area of the color filter substrate 330, e.g., each pixel of the color filter substrate 330.

Note that, the cameras 302a and 302b are provided at equal angles with respect to a center line O vertically passing through a substantially central part of the surface of the color filter substrate 330 which is the evaluation target. Further, as in the cameras 320a and 320b, also the illumination devices 310a and 310b are provided at equal angles with respect to the center line O vertically passing through the substantially central part of the surface of the color filter substrate 330 which is the evaluation target. As a result, two kinds of images obtained at angles opposite to each other can be taken from the color filter substrate 330 which is a single evaluation target. This point will be detailed later.

Information obtained as a result of the evaluation carried out by the evaluation device 100 is outputted to the result output device 500 as a specific cycle uneven streaks evaluation value indicative of evaluation of a below-described appearance tendency of the specific cycle uneven streaks. Note that, the evaluation device 100 will be detailed later.

In the result outputting device 500, data which allows an operator to confirm the inputted specific cycle uneven streaks evaluation value, e.g., data in the form of graph is outputted as result data. The output result will be described later.

Further, the data storage device 400 is connected to the evaluation device 100. In the data storage device 400, the image data obtained by imaging the color filter substrate 330 with the cameras 320a and 320b is stored, and various kinds of data such as an evaluation value (detailed later) obtained by the evaluation device 100 are stored.

The color filter substrate 330 is formed as follows.

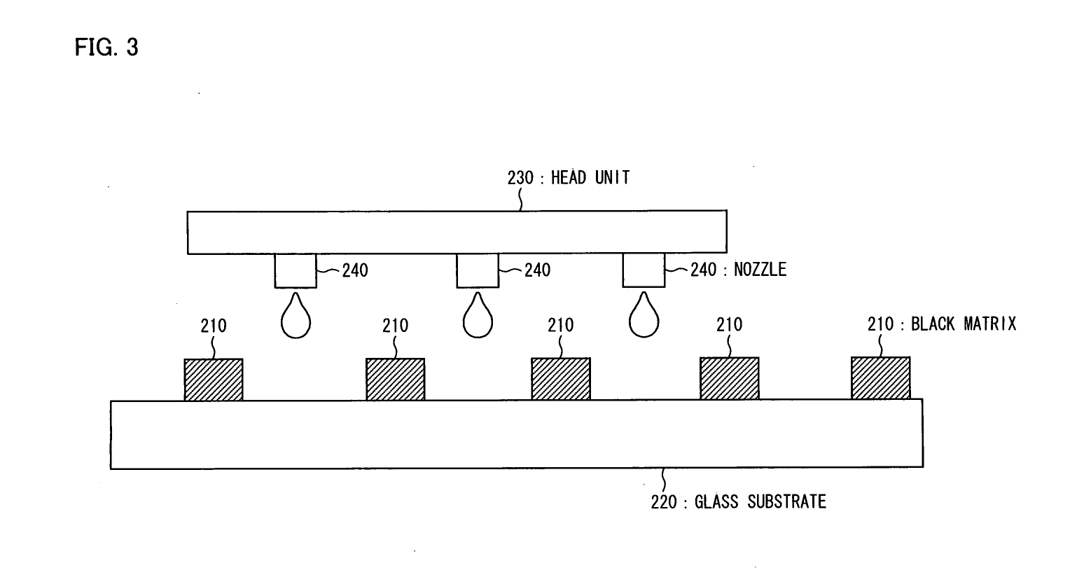

FIG. 3 is a drawing illustrating part of manufacturing step (manufacturing method) of the color filter substrate 330 and a step of ejecting color filter liquid material in accordance with the inkjet process. With respect to a glass substrate 220 on which a black matrix 210 has been formed, a head unit 230 moves in a scanning direction (inward direction of the paper or outward direction of the paper) and inkjet nozzles 240 respectively eject liquid materials, sequentially in the scanning direction, onto the glass substrate 220 so that each liquid material is landed on each portion exposed at the black matrix 210. Further, when the ejection in the scanning direction is completed, the head unit 230 moves in a direction orthogonal to the scanning direction (i.e., moves in a horizontal direction in the figure) at a predetermined distance and then moves in the scanning direction (inward direction of the paper or outward direction of the paper) again, and the inkjet nozzles 240 respectively eject liquid materials sequentially in the scanning direction. Repetition of the operation of the head unit 230 causes a color filter to be formed on the color filter substrate 330.

At this time, in case where amounts of liquid materials ejected by the nozzles 240 of the head unit 230 are uneven for some cause or in a similar case, the resultant color filter has uneven streaks corresponding to intervals of the nozzles.

Further, in case where the nozzles are partially clogged for some cause or in a similar case, the resultant color filter has uneven streaks corresponding to intervals of the head unit 230. Specifically, uneven streaks occurs corresponding to each number of the nozzles 240 of the head unit 230 in the direction orthogonal to the scanning direction. In FIG. 2 for example, uneven streaks occurs corresponding to every three nozzles 240 in the scanning direction.

In this manner, in case where the color filter substrate 330 is formed by the inkjet process, uneven streaks at various cycles (specific cycle uneven streaks) occur depending on causes of occurrence.

Such uneven streaks are clearly found by causing the cameras 320a and 320b serving as the imaging means of FIG. 2 to image light corresponding to the uneven streaks.

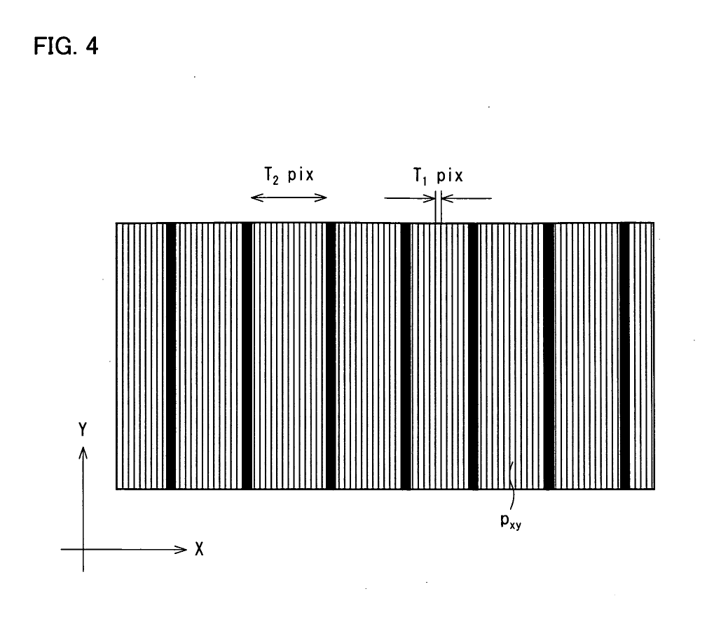

FIG. 4 illustrates an example of an image obtained by causing the cameras 320a and 320b to image the color filter substrate 330 in a plane manner (two-dimensional manner). Herein, this shows uneven streaks which occur in case of using the head unit 230. In the obtained image, a direction parallel to an uneven streaks direction is defined as “Y direction”, and a direction perpendicular to the uneven streaks direction is defined as “X direction”. Herein, the uneven streaks refer to unevenness in a plural streaks which unevenness is caused by differences in the film thickness on the color filter formation surface of the color filter substrate 330. Thus, the uneven streaks direction is a longitudinal direction of the formed streaks.

In the present invention, the evaluation device 100 evaluates uneven streaks, occurring at a specific cycle on the color filter formed on the surface of the color filter substrate 330, in accordance with two-dimensional luminance distribution information (light distribution information) extracted from the planar image of the color filter substrate 330. The evaluation includes information concerning an appearance intensity of uneven streaks and a direction in which the uneven streaks occur. By the evaluation, the user can find an appearance tendency of specific cycle uneven streaks on the surface of the color filter substrate 330.

In the present invention, the evaluation device 100 provided on the specific cycle uneven streaks evaluation system 300 provides information for evaluating uneven streaks, occurring at a specific cycle on the color filter formed on the surface of the color filter substrate 330, in accordance with two-dimensional luminance distribution information (light distribution information) extracted from the planar image of the color filter substrate 330.

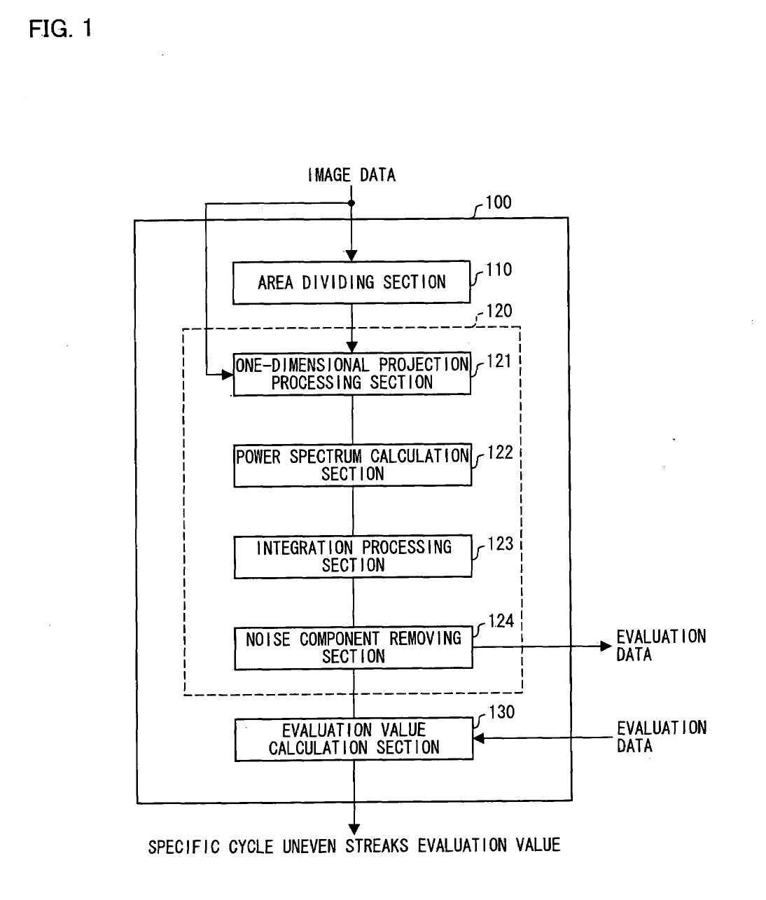

FIG. 1 is a schematic block diagram of the evaluation device 100.

As described above, the evaluation device 100 has a function for outputting, as information for evaluating uneven streaks, an evaluation value for evaluating specific cycle uneven streaks in accordance with image information obtained by the cameras 320a and 320b of the specific cycle uneven streaks evaluation system 300, to the result outputting device 500.

As illustrated in FIG. 1, the evaluation device 100 includes an area dividing section 110, an evaluation data generation section 120, and an evaluation calculation section 130.

Specifically, in the evaluation device 100, the area dividing section 110 or the evaluation data generation section 120 obtains image information from the data storage device 400 or the cameras 320a and 320b in response to a command of a CPU (not shown).

The area dividing section 110 divides the image data into areas each of which has a preset size so as to output image data, corresponding to each area of the image data, to the evaluation data generation section 120 at the subsequent stage.

As to an area in a direction in which the light distribution information obtained from the evaluation target is one-dimensionally projected, generally, a great noise occurs when the area is short, and necessary information is likely to be buried when the area is long. Thus, the length of the area is set to be equal to 512 pixel for example. Further, an area in a direction orthogonal to the direction in which the one-dimensional projection is carried out is set so as to be within a range expected to have uneven streaks. In this manner, the length of the direction in which the first-dimensional projection is carried out in each area and the length of the direction orthogonal to the direction are set. Note that, the range expected to have uneven streaks is estimated in accordance with a color filter plotting method, a size of a plotting head unit, and the like.

Further, in dividing the image data into areas, the area dividing section 110 may cause the areas to overlap with each other so that uneven streaks occur at a specific cycle in the same area. By overlapping the areas with each other in this manner, it is possible to evaluate whole the areas of the evaluation target without any omission, so that it is possible to improve accuracy of the uneven streaks evaluation.

The evaluation data generation section 120 includes a one-dimensional projection processing section 121, a power spectrum calculation section 122, an integration processing section 123, and a noise component removing section 124.

The one-dimensional projection processing section 121 converts the two-dimensional luminance distribution information included in the inputted image data into one-dimensional luminance distribution information. The one-dimensional projection process carried out by the one-dimensional projection processing section 121 will be detailed later. Further, the one-dimensional projection processing section 121 outputs a one-dimensional projection process result to the power spectrum calculation section 122 at the subsequent stage.

The power spectrum calculation section 122 carries out Fourier transform of the inputted one-dimensional luminance distribution information and analyzes periodicity of the one-dimensional luminance distribution information so as to calculate a power spectrum. A cycle analysis process carried out by the power spectrum calculation section 122 will be detailed later. Further, the power spectrum calculation section 122 outputs the one-dimensional luminance distribution information, having been subjected to Fourier transform, to the integration processing section 123 at the subsequent stage, in combination with the cycle analysis result.

The integration processing section 123 carries out an integration process with respect to the inputted one-dimensional luminance distribution information, having been subjected to Fourier transform, in a preset interval. Further, the integration processing section 123 output the one-dimensional luminance distribution information, having been subjected to the integration process, to the noise component removing section 124 at the subsequent stage.

The noise component removing section 124 specifies an interval integral value of the noise component in accordance with an inputted interval integral value, and divides the interval integral value of the noise component in accordance with an interval integral value of the specific cycle uneven streaks, so as to generate evaluation data of the specific cycle uneven streaks. The generated evaluation data is temporarily stored in the aforementioned data storage device 400 or is outputted to the evaluation value calculation section 130 at the subsequent stage.

The evaluation value calculation section 130 calculates an evaluation value of specific cycle uneven streaks occurring on the color filter of the color filter substrate 330, i.e., the evaluation target, in accordance with the evaluation data inputted from the noise component removing section 124 or stored in the data storage device 400. The calculation will be detailed later.

Further, the evaluation value calculation section 130 outputs the calculated result to the result outputting device 500 at the subsequent stage as the evaluation value of the specific cycle uneven streaks.

The result outputting device 500 outputs the inputted evaluation value in the form which is easy for a human to recognize, e.g., in the form of a graph. With reference to the outputted result, an operator evaluates cyclic uneven streaks on the color filter formed on the surface of the color filter substrate 330. Thus, the result outputted from the result outputting device 500 may be in any manner as long as the operator can recognize the result.

Herein, the following details (i) how the specific cycle uneven streaks evaluation system 300 determines whether uneven streaks are cyclic or not and (ii) how the specific cycle uneven streaks are evaluated.

As to light reflected by the cameras 320a and 320b of the specific cycle uneven streaks evaluation system 300, reflected light is greatly intense at a pixel of the color filter substrate 330 which pixel has a greater thickness than that of other area, and reflected light is less intense at a pixel of the color filter substrate 330 which pixel has a smaller thickness than that of other area. The difference in the reflected light intensity is recognized as unevenness.

Note that, generally, due to the aforementioned reason, the film thickness difference caused by the inkjet process is likely to occur in a row in the scanning direction. In case where the film thickness difference occurs in a row, uneven streaks are observed in image data obtained by the camera (detection means) 320.

Note that, as described above, due to a human visual sense characteristic, uneven streaks which occur cyclically are conspicuous out of uneven streaks which occur on the color filter substrate 330. Thus, in order to improve the quality, it is important to determine whether any cyclic uneven streaks occur or not.

The following describes how the evaluation device 100 carries out a process for determining whether uneven streaks are cyclic or not. Whether uneven streaks are cyclic or not is determined by the one-dimensional projection processing section 121 and the power spectrum calculation section 122 of the evaluation device 100. Note that, the integration processing section 123 and the noise component removing section 124 of the evaluation device 100 evaluate specific cycle uneven streaks.

First, how the one-dimensional projection processing section 121 carries out the one-dimensional projection process is described as follows.

FIG. 4 illustrates an example of an image obtained by the cameras 320a and 320b serving as the imaging means. Note that, the one-dimensional projection processing section 121 carries out the one-dimensional projection process with respect to the light distribution information included in the image data (FIG. 4 for example) obtained by the cameras 320a and 320b so that a projection direction is a direction including a vector in a direction in which uneven streaks occur. Herein, the projection direction is a direction in which a luminance value is added along the aforementioned uneven streaks direction (i.e., the projection direction is a direction in which the one-dimensional projection process is carried out). In the present embodiment, as illustrated in FIG. 4, the projection direction is a Y direction parallel to the uneven streaks direction in the image.

Thus, in the one-dimensional projection process of the present embodiment, with respect to the image of FIG. 4, luminance values are averaged in the Y direction so as to convert the two-dimensional luminance distribution information into one-dimensional information.

Herein, the luminance distribution information of the obtained image is represented by p, x, and y. “x” is a coordinate axis value in the X direction, and “y” is a coordinate axis value in the Y direction. With this, the one-dimensional luminance distribution information is obtained in accordance with the following expression (1).

$${P}_{x} = \frac{1}{N} {\sum }_{y = 1}^{N} {p}_{xy} \qquad ( 1 )$$

where N is the number of data sets in the Y direction.

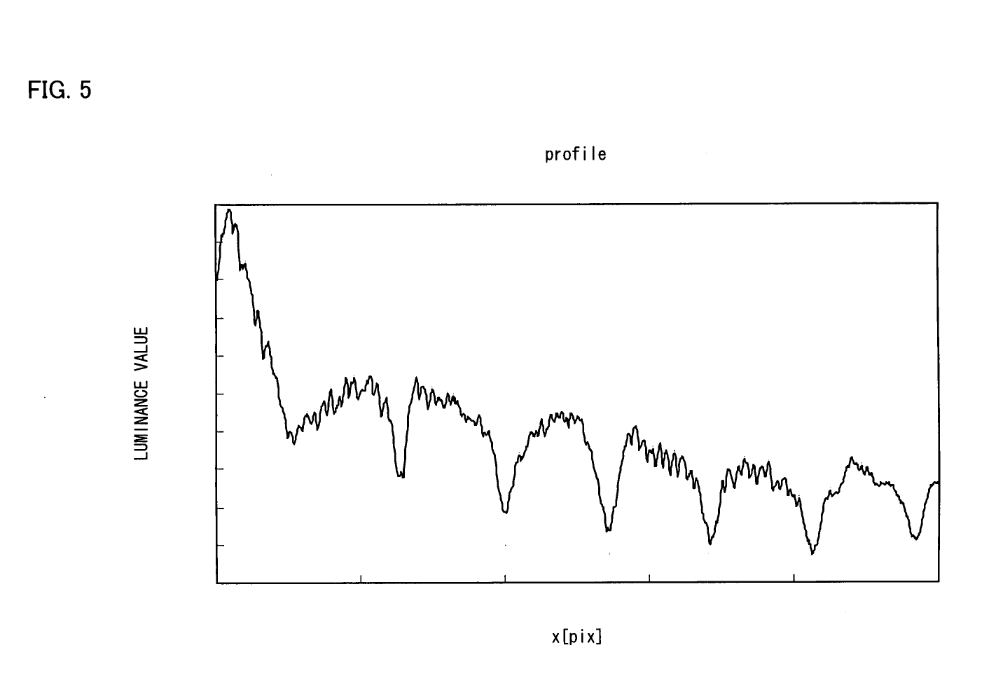

FIG. 5 is a graph showing the one-dimensional luminance distribution information having been calculated in accordance with the expression (1). A vertical axis indicates a luminance value, and a horizontal axis indicates a position of an X coordinate. Note that, a unit of the horizontal axis is “pixel”.

The one-dimensional luminance distribution information calculated in this manner is subjected to Fourier transform by the power spectrum calculation section 122 at the subsequent stage.

Note that, in the present embodiment, the method in which luminance values are averaged is adopted as an example of the one-dimensional projection process. However, the one-dimensional projection process is not particularly limited to this as long as the two-dimensional data can be converted into one-dimensional data. For example, it is possible to adopt a method in which luminance values are integrated in the Y direction or it is possible to adopt a method in which luminance values are weighted and added to each other.

Next, how the power spectrum calculation section 122 carries out the cycle analysis process is described as follows.

The power spectrum calculation section 122 carries out Fourier transform by using the following expression (2).

$${A}_{k} = {\sum }_{x = 1}^{N} {P}_{x} {e}^{- 2 π lxk / N} \qquad ( 2 )$$

By carrying out Fourier transform in accordance with the foregoing expression (2), it is possible to calculate a distribution of frequencies. Further, calculation of inverse numbers of frequencies results in a function of the cycle.

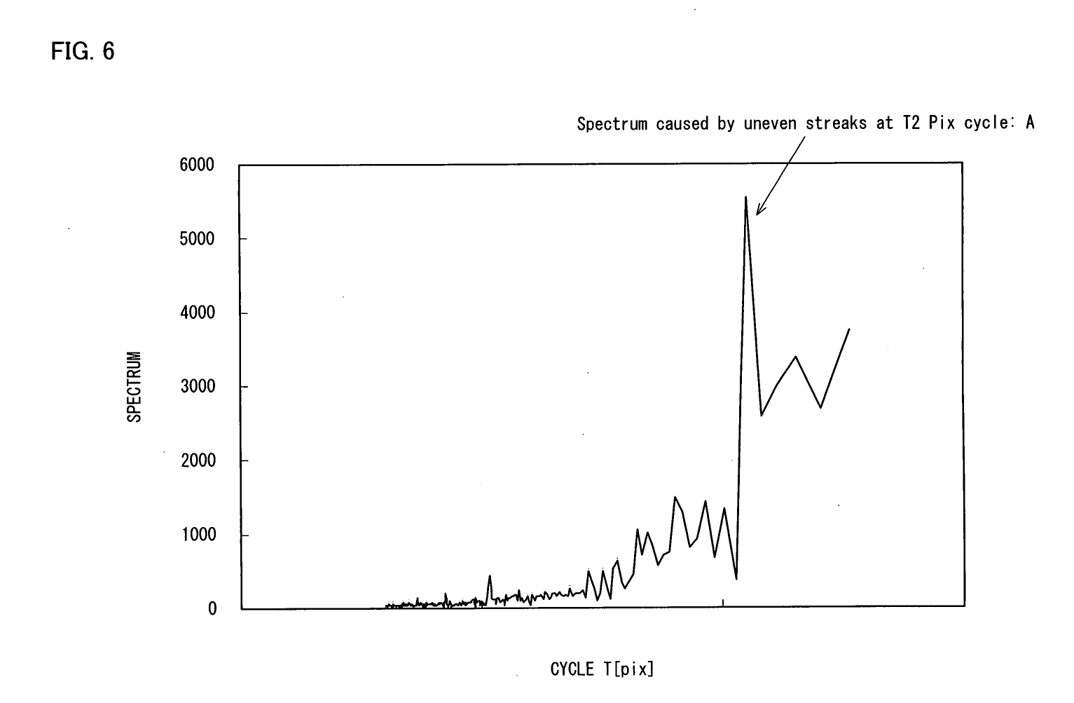

FIG. 6 is a graph showing a result of Fourier transform carried out with respect to the data (graph shown in FIG. 5) having been subjected to the one-dimensional projection by the one-dimensional projection processing section 121. A vertical axis indicates an intensity of a spectrum. A horizontal axis indicates a logarithm obtained by converting an inverse number of a frequency into a cycle. Note that, a unit of the cycle is “pixel”.

This graph shows a part A (spectrum caused by uneven streaks having a T2 Pix cycle) in which a conspicuous spectrum is observed. This shows that cyclic uneven streaks occur. By carrying out the Fourier transform in this manner, it is possible to obtain data (unevenness cycle information) indicative of whether uneven streaks occurring on the color filter substrate 330 are cyclic or not.

Herein, the unevenness cycle information is outputted in the form of a graph or the like which can be recognized by the operator at the result outputting device 500, so that the operator can determine whether uneven streaks are cyclic or not.

Note that, the determination of whether uneven streaks are cyclic or not may be automatically carried out in accordance with a relation between the spectrum included in the unevenness cycle information and the cycle instead of the aforementioned operation in which the operator determines by viewing with eyes.

For example, the determination of whether uneven streaks are cyclic or not, i.e., determination of whether a conspicuous spectrum is observed or not can be automatically made by carrying out an operation in which determination reference information having been stored in advance is read out and the read out information is compared with the detected spectrum. The determination reference information is registered in a determination reference database. The determination reference database may be provided in the result outputting device 500 of the specific cycle uneven streaks evaluation system 300 or may be separately provided.

A specific example thereof is the following method: a moving average of FIG. 6 is obtained, and a vicinity of the moving average (e.g., a range from an upper limit obtained by multiplying the moving average by 1.2 to a lower limit obtained by multiplying the moving average by 0.8) is regarded as the determination reference information, and whether or not there is a spectrum value deviating from this range is determined, thereby automatically determines whether uneven streaks are cyclic or not. Further, whether uneven streaks are cyclic or not may be determined by other various kinds of methods.

Further, as described above, uneven streaks of various cycles occur depending on causes of occurrence, so that it is possible to adopt an arrangement in which: information including a width and a cycle of expected uneven streaks is registered in the determination reference information with it associated to the cause of occurrence of the uneven streaks, and the width and the cycle of the uneven streaks which are included in the detected unevenness cycle information and the registered information are referred to so as to specify the cause of occurrence of the uneven streaks.

For example, as the information registered in the determination reference database, there is used a vicinity value range including a cycle of uneven streaks associated to a cause of occurrence of the uneven streaks and a vicinity range thereof. Further, whether or not a cycle included in the unevenness cycle information is included in the vicinity value range of the cycle registered in the determination reference database is confirmed sequentially with respect to cycles having been registered, and determination is given depending on whether or not the cycle is included in the vicinity value range of the registered cycle. At this time, if the cycle of the uneven streaks included in the detected unevenness cycle information is determined as being included in the vicinity value range of the registered cycle, it is possible to specify a cause of occurrence of the uneven streaks occurring at the cycle.

Herein, the cycle is set so as to cover the vicinity value range as preparation against the case where any error occurs due to positional deviation of the head unit or other factor. Taking the error into consideration, the range is set. For example, the vicinity value range is determined in accordance with a size error value, an operation error value, etc., and an empirical value, and the like, concerning mechanisms of the head, the nozzles, the scanning stage, and the like. Further, it may be so arranged that information concerning the width of the uneven streaks is added to the determination reference database so as to carry out the determination.

As described above, by determining whether uneven streaks are cyclic or not, it is possible to refer to the determination result in the manufacturing step as feedback.

Further, a conspicuous spectrum occurs in the vicinity of T2 pixel, which shows that a cycle of the uneven streaks is about T2 pixel. In this manner, the Fourier transform also allows the cycle of the uneven streaks to be calculated.

If whether uneven streaks are cyclic or not is determined in the foregoing manner, it is possible to improve the productivity (yield) to some extent by referring to the determination result in the manufacturing step of the color filter as feedback.

However, in improving the productivity, mere detection of the uneven streaks occurring at a cycle is insufficient. That is, even if uneven streaks occurring at a cycle is detected, it is impossible to appropriately adjust the head unit for manufacturing the color filter unless an intensity and a direction of the detected uneven streaks are specified.

In case where cyclic uneven streaks are detected, particularly in case where uneven streaks occurring at a problematic specific cycle are detected, an evaluation value serving as an index indicative of the appearance intensity, the occurrence direction, or the like of the specific cycle uneven streaks is calculated and used, thereby appropriately adjusting the head unit so as to correspond to the uneven streaks occurring at the problematic specific cycle. As a result, it is possible to improve the productivity of the color filter.

The following describes how to evaluate uneven streaks, i.e., how to calculate an evaluation value of uneven streaks.

The evaluation of uneven streaks means to specify an occurrence intensity (luminance intensity) and an occurrence point of uneven streaks.

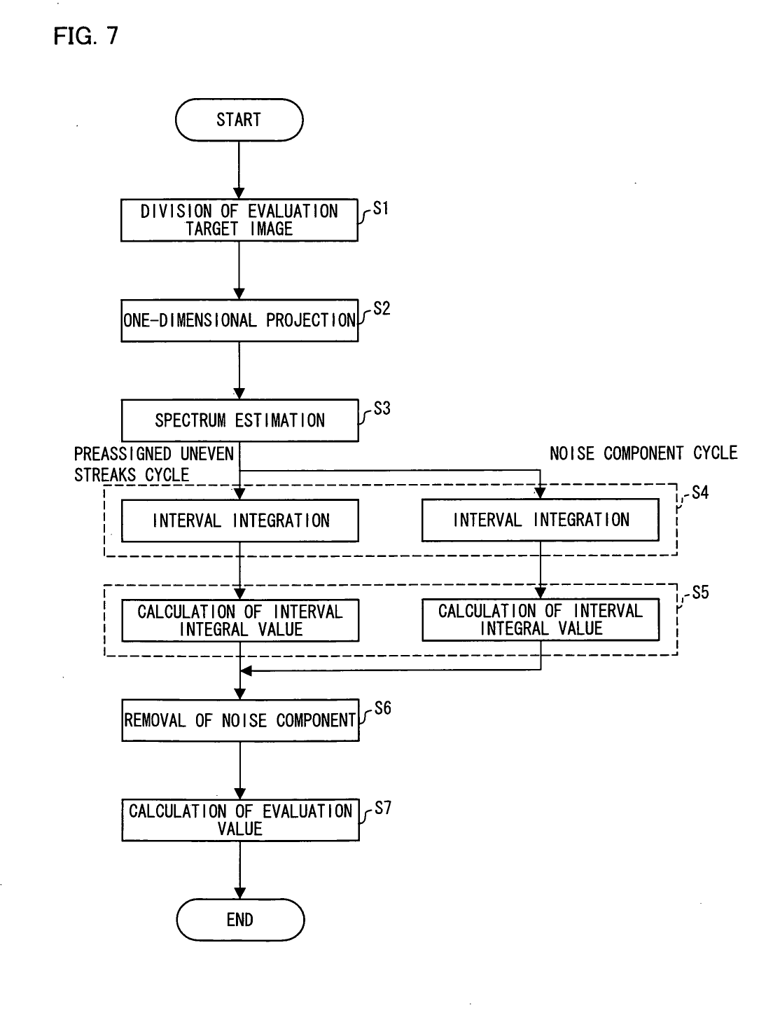

FIG. 7 is a flowchart showing an evaluation process carried out by the evaluation device 100 of FIG. 1.

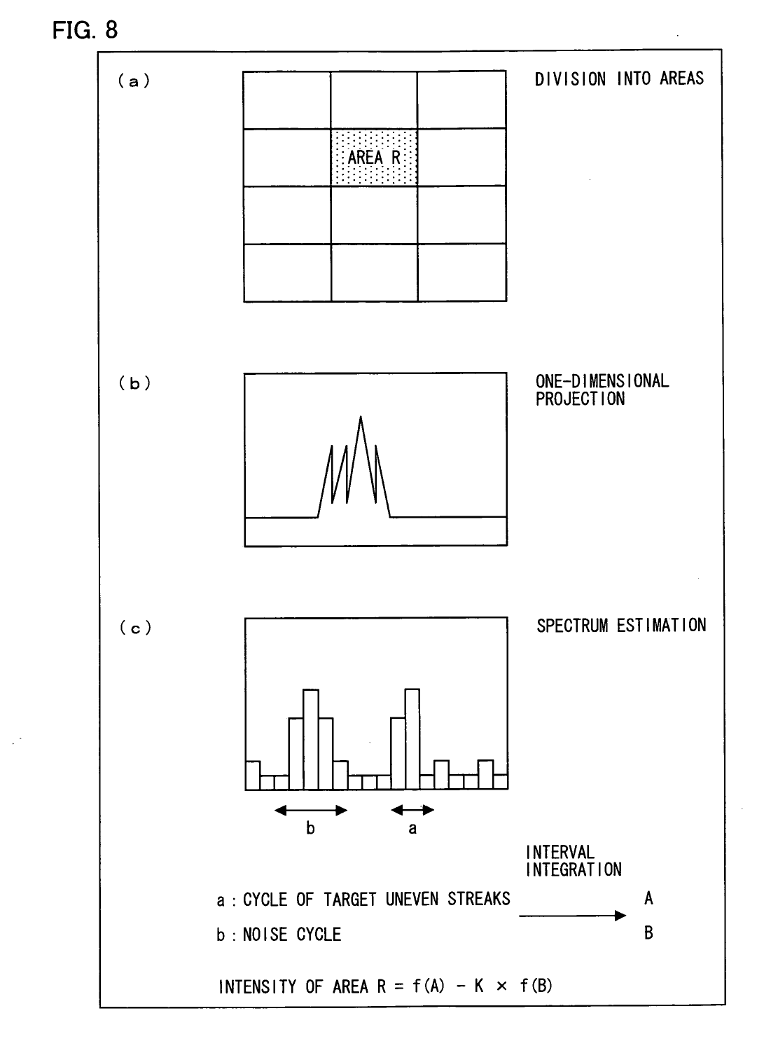

First, the area dividing section 110 divides an area of an image to be evaluated (step S1). Herein, the image to be evaluated is an image obtained by imaging the surface of the color filter substrate 330 which is the evaluation target. Further, as to the division of the image data, data of a single image may be divided into 12 areas as illustrated in (a) of FIG. 8 for example. A size of each area is set in advance.

The foregoing step S1 may be omitted. That is, the one-dimensional projection process may be carried out without dividing the image to be evaluated. However, by dividing the image to be evaluated in the step S1, it is possible to evaluate not only the entire image to be evaluated but also each area.

Next, the one-dimensional projection section 121 of the evaluation data generation section 120 carries out the one-dimensional projection process with respect to each area of the image (step S2). In case of carrying out the one-dimensional projection process with respect to an area R of the divided areas of (a) of FIG. 8 for example, this is illustrated by a graph whose horizontal axis represents a pixel position and whose vertical axis represents a luminance value as shown in (b) of FIG. 8 for example. This graph is as in the graph of FIG. 5.

As described in the step S2, by carrying out the one-dimensional projection process with respect to the image to be evaluated, it is possible to improve an S/N ratio. That is, it is possible to clearly distinguish a noise component and a signal component (uneven streaks) from each other.

Subsequently, the power spectrum calculation section 122 of the evaluation data generation section 120 carries out spectrum estimation in accordance with the image data having been subjected to the one-dimensional projection process (step S3). The spectrum estimation means to analyze a cycle of the image data having been subjected to the one-dimensional projection process so as to obtain a power spectrum. This is shown by a graph of (c) of FIG. 8 for example. As in (b) of FIG. 8, a horizontal axis indicates a pixel position and a vertical axis indicates a spectrum intensity in this graph.

Subsequently, the integration processing section 123 in the evaluation data generation section 120 carries out an interval integration (step S4). Herein, (c) of FIG. 8 shows that an interval integration is carried out with respect to a vicinity of a cycle a of target uneven streaks (preassigned uneven streaks cycle) and an interval integration is carried out with respect to a vicinity of a noise cycle b (noise component cycle).

Subsequently, the integration processing section 123 calculates an interval integration value of each cycle (step S5). Herein, an interval integral value obtained by carrying out interval integration in the vicinity of the cycle a of target uneven streaks is defined as “A”, and an interval integral value obtained by carrying out interval integration in the vicinity of the noise cycle b is defined as “B”, and the integration processing section 123 outputs the interval integral values to the noise component removing section 124 at the subsequent stage.

Next, the noise component removing section 124 carries out the noise component removal (step S6). Herein, an interval integral value in the cycle a of target uneven streaks is defined as “A”, and an interval integral value in the noise cycle b is defined as “B”, and a noise component is removed in accordance with the following expression 3, thereby calculating an intensity of the area R.

Intensity of area R=f(A)−Kf(B) (3)

where K is an arbitrary coefficient.

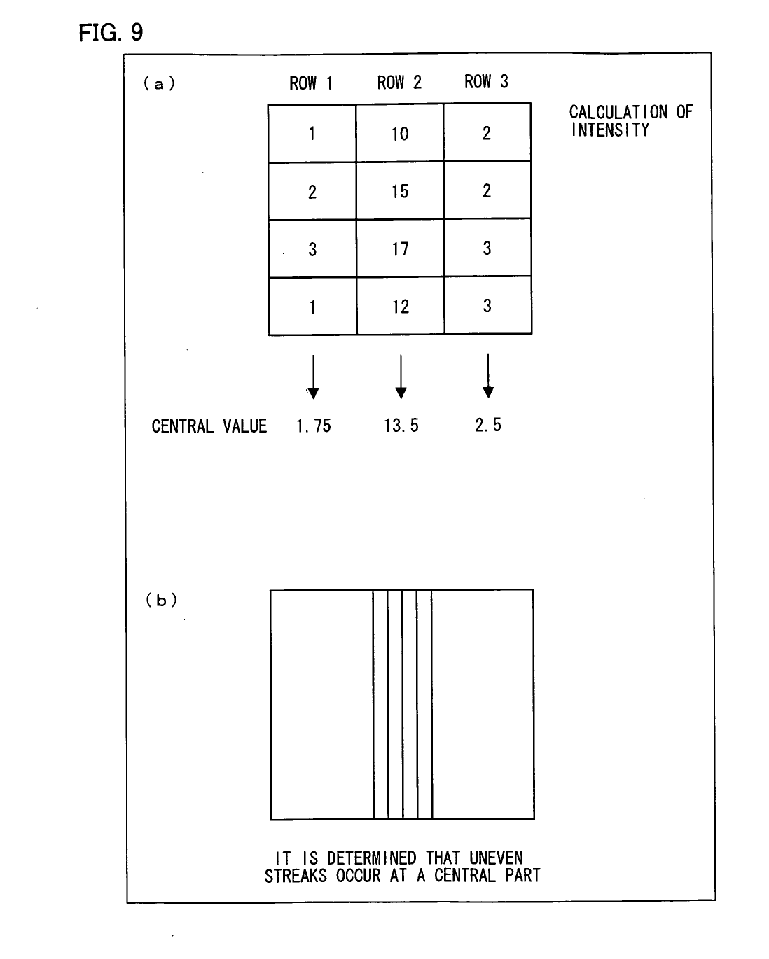

In the foregoing expression (3), a value indicative of an intensity of each of the areas of the image to be evaluated, i.e., a value indicative of an occurrence intensity of uneven streaks is calculated. The value indicative of the intensity is calculated in each of the areas as evaluation data as illustrated in (a) of FIG. 9.

The noise component removing section 124 outputs the evaluation data to the evaluation value calculation section 130 at the subsequent stage or to the data storage device 400.

Subsequently, the evaluation value calculation section 130 calculates the evaluation value (step S7). Herein, evaluation data sets in each of rows 1 to 3 at each area illustrated in (a) of FIG. 9 are averaged, and the thus obtained average value is regarded as a central value of each row. The central value is outputted to the result outputting device 500 at the subsequent stage as a specific cycle uneven streaks evaluation value.

The central value may be obtained by arithmetic average, rms (root mean square), or the like, as well as the aforementioned method in which evaluation data sets in the row direction are averaged. In case where uneven streaks occur sequentially in the vertical direction or in a similar case, evaluation results (evaluation data sets) are integrated, thereby improving an S/N ratio of uneven streaks evaluation. That is, it is possible to improve accuracy of uneven streaks evaluation.

As illustrated in (b) of FIG. 9, the result outputting device 500 outputs data indicative of occurrence of uneven streaks in a central part of the obtained image in accordance with the inputted specific cycle uneven streaks evaluation value. As described above, the outputted data may be in any manner as long as the user can specify a position at which uneven streaks occur on the image and an intensity of the uneven streaks.

The foregoing description explained the example where a single camera is used to image the evaluation target. However, the specific cycle uneven streaks evaluation system 300 arranged in the foregoing manner includes two cameras, so that the following description will explain an example where two cameras are used.

In the specific cycle uneven streaks evaluation system 300 of FIG. 2, the cameras 320a and 320b can image the evaluation target from different angles. Further, with respect to a center line O passing through substantially the center of the surface of the color filter substrate 330 which is the evaluation target, the cameras 320a and 320b are provided with them inclined at the same angle. Further, as in the cameras 320a and 320b, also the illumination devices 310a and 310b are provided, with them inclined at the same angle, with respect to the center line O passing through substantially the center of the surface of the color filter substrate 330.

However, an angle at which each camera images the evaluation target may be freely changed as long as the evaluation target can be imaged from different angles. A favorable angle is such an angle that a size of a noise component included in the image obtained by the one camera is different from a size of the noise component included in the image obtained by the other camera. By adjusting the angles so that the size of the noise component seems to vary in this manner, it is possible to highly accurately specify the noise component occurring on the surface of the evaluation target. As a result, it is possible to appropriately evaluate the specific cycle uneven streaks.

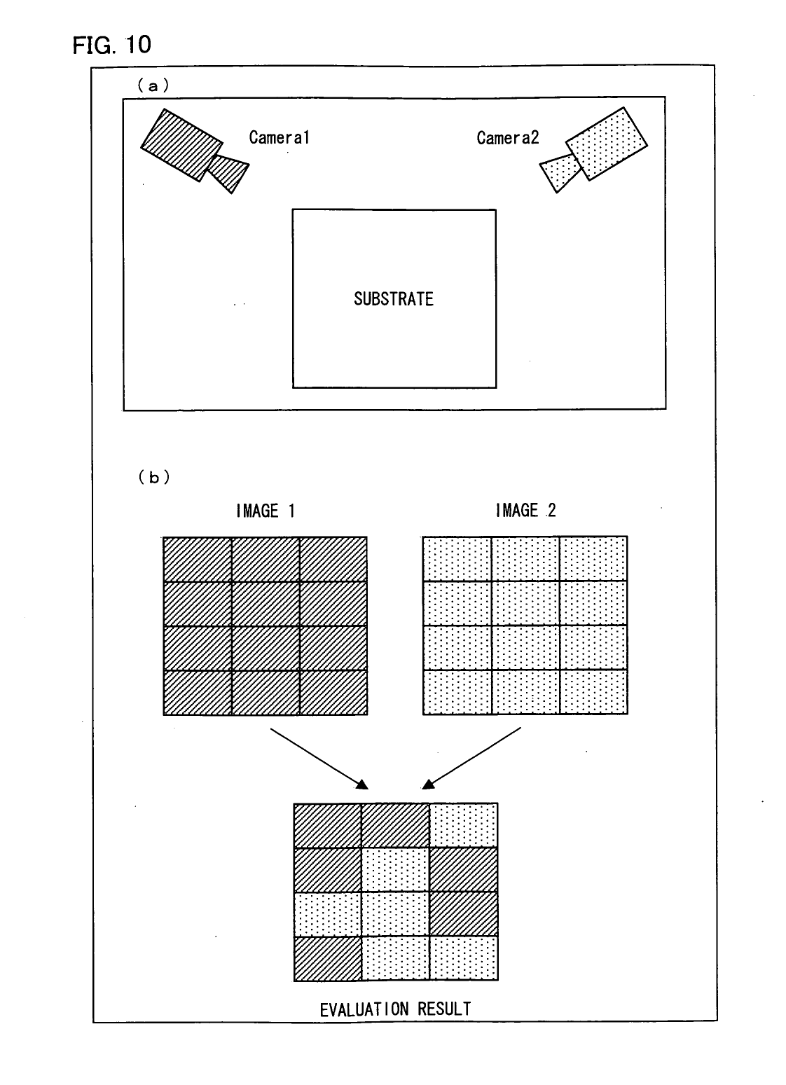

For example, as illustrated in (a) of FIG. 10, if two cameras (Camera 1 and Camera 2) respectively image the substrate serving as the evaluation target, it is possible to obtain two kinds of images, i.e., an image 1 and an image 2, as illustrated in (b) of FIG. 10. Further, the two images 1 and 2 are synthesized so as to obtain an evaluation result. Herein, the images 1 and 2 are different from each other in a size of a noise component.

By imaging the evaluation target from different angles in this manner, it is possible to obtain images different from each other in the size of the noise component. This allows for use of an evaluation result obtained from the direction in which the size of the noise component is smaller, so that it is possible to evaluate uneven streaks with higher accuracy.

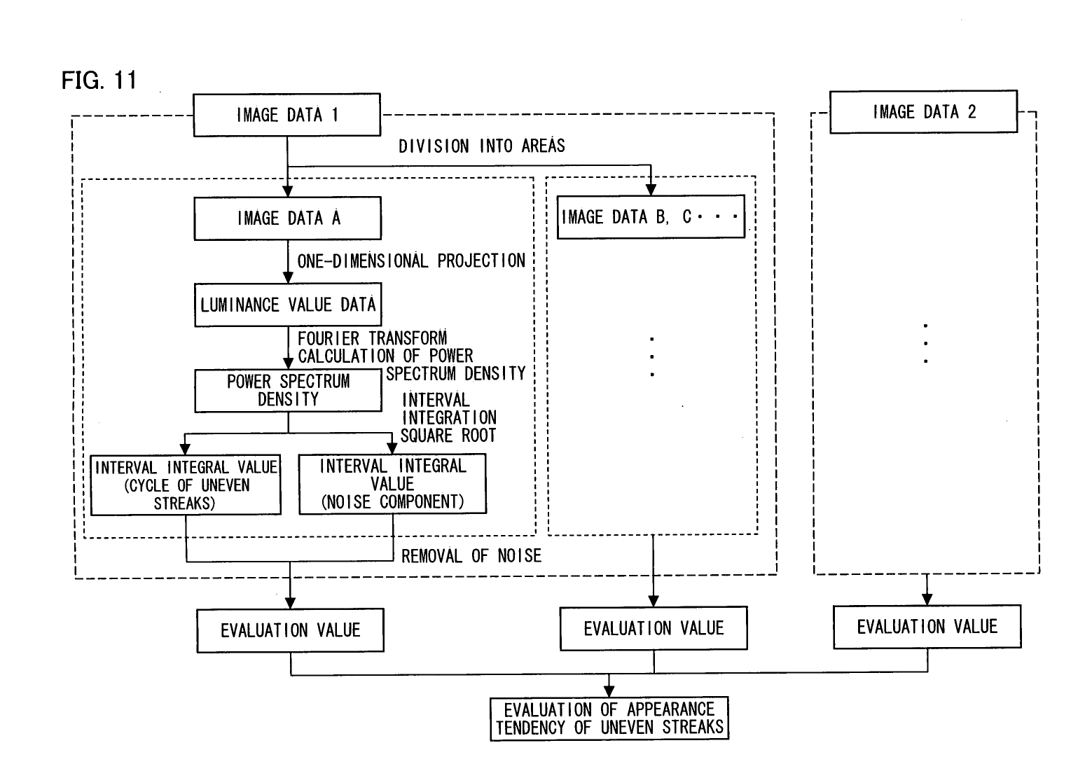

With reference to FIG. 1, FIG. 2, and FIG. 11, this point is detailed as follows.

FIG. 11 illustrates a specific example of a process carried out in the specific cycle uneven streaks evaluation system 300 in case of using two cameras. Image data 1 is data of an image obtained by the camera 320a, and image data 2 is data of an image obtained by the camera 320b.

Each image data obtained by each camera is inputted to the evaluation device 100, and then the below-described process is carried out. Herein, the image obtained by the camera 320a is the image data 1, and the image obtained by the camera 320b is the image data 2.

First, the image data 1 inputted to the evaluation device 100 is divided into areas by the area dividing section 110. Herein, the image data 1 is divided into image data A, image data B, . . . . The image data is divided in this manner, thereby evaluating the specific uneven streaks with higher accuracy. The following process is carried out for each of the image data A, the image data B, . . . .

Next, the image data having been divided into areas is subjected to one-dimensional projection by the one-dimensional projection processing section 121 of the evaluation data generation section 120 so as to be one-dimensional luminance value data. By converting the obtained image data into the one-dimensional luminance value data in this manner, it is possible to suppress unevenness of luminance values included in the image data, thereby improving the S/N ratio. Further, by converting the obtained image data into the one-dimensional luminance value data, it is possible to improve a data calculation rate.

Next, the one-dimensional luminance value data is subjected to Fourier transform (cycle analysis) by the cycle analysis processing section 122. Further, a power spectrum and a power spectrum density are calculated in accordance with the Fourier transform result. This makes it possible to show an intensity of each frequency component.

Next, with respect to the power spectrum density obtained by the cycle analysis processing section 122, the integration processing section 123 carries out an interval integration corresponding to a preset uneven streaks cycle period of the evaluation target, thereby calculating an interval integral value. As a result, it is possible to evaluate an intensity of uneven streaks occurring in an uneven streaks cycle interval. Further, at this time, the uneven streaks cycle may be set in accordance with a result of spectrum estimation. For example, by setting an interval with respect to the vicinity of a spectrum cycle having the highest intensity in accordance with the result of spectrum estimation, it is possible to evaluate a cycle and an intensity of uneven streaks occurring in the image data. Note that, it is also possible to adopt a square root of the result of the interval integration in calculating the interval integration value.

Next, as in the interval integral value concerning the uneven streaks cycle of the evaluation target, with respect to the power spectrum density, an interval integration is carried out corresponding to a preset uneven streaks cycle period, thereby calculating a specific interval integral value. This makes it possible to evaluate an intensity of a noise which occurs in the noise cycle interval. Further, at this time, the cycle of the noise may be set in accordance with the result of the spectrum estimation. For example, by setting an interval with respect to the vicinity of a spectrum cycle having an intensity not less than a certain threshold value in accordance with the result of the spectrum estimation, it is possible to evaluate a cycle and an intensity of uneven streaks occurring in the image data. Note that, it is also possible to adopt a square root of the result of the interval integration in calculating the interval integral value.

Next, the noise component removing section 124 removes a noise from the interval integral value of the uneven streaks cycle component by using the interval integral value of the noise component, thereby calculating an evaluation value. At this time, in case where, for example, the interval integral value of the uneven streaks cycle component is A and the interval integral value of the noise component is N taking into consideration an influence exerted by the noise component onto the interval integral value of the uneven streaks cycle component, an evaluation value (evaluation data) S can be calculated in accordance with the following expression (4).

S=A−KN (K is a constant number) (4)

In the foregoing manner, the evaluation value S is generated by the evaluation data generation section 120.

Next, the evaluation value calculation section 130 synthesizes evaluation values S calculated with respect to the image data A, the image data B, . . . . This makes it possible to evaluate an appearance tendency of uneven streaks in the entire image data. For example, out of evaluation values of the areas obtained by dividing the image data, evaluation values of areas in a vertical direction are synthesized, thereby improving evaluation accuracy in case where uneven streaks in a straight line manner occur in the vertical direction. In case of evaluating the color filter substrate, uneven streaks are likely to occur in a straight line manner, so that it is extremely effective to synthesize evaluation results in the vertical direction. Also, it is possible to synthesize evaluation results in a horizontal direction likewise. Herein, in case where the one direction is determined, a direction orthogonal to the determined direction is the other direction. In this manner, a vertical direction and a horizontal direction may be determined. Further, a direction in which uneven streaks occur is determined as a synthesizing direction.

The uneven streaks evaluation is carried out with respect to single image data 1 in the foregoing manner. Likewise, the same process as in the image data 1 is carried out with respect to second image data (image data 2) so as to carry out evaluation.

Further, the resultant evaluation value of the image data 1 and the resultant evaluation value of the image data 2 are synthesized so as to obtain an evaluation value of specific cycle uneven streaks in the evaluation target.

As a result, by calculating evaluation values with respect to data sets of images obtained by imaging the evaluation target from plural directions, it is possible to adopt an evaluation value in a direction which allows less generation of a noise component, thereby improving evaluation accuracy. For example, in calculating evaluation values from plural image data sets, a characteristic quantity of the noise component is used. Herein, by calculating an evaluation value concerning such image data that a characteristic quantity of the noise component is small, it is possible to improve the evaluation accuracy.

In case where uneven streaks of a different cycle is included in the evaluation target, it is possible to accurately evaluate uneven streaks of each cycle as long as the noise component can be appropriately removed.

The following describes how the noise component removing section 124 removes the noise component.

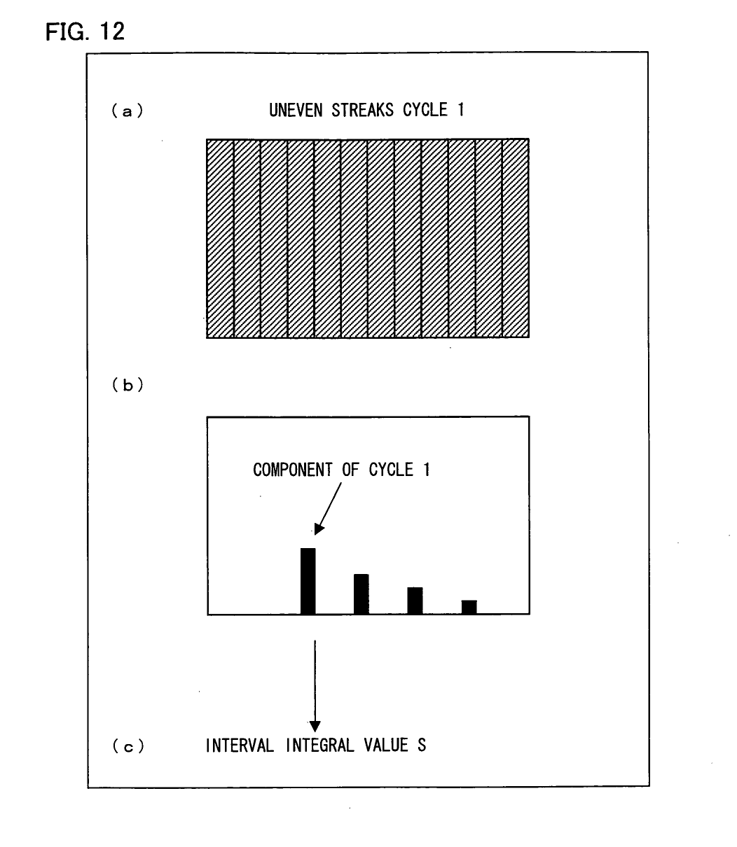

Each of FIG. 12 to FIG. 14 illustrates a technique for removing a noise.

First, with respect to an image having an uneven streaks cycle 1 illustrated in (a) of FIG. 12, spectrum estimation is carried out ((b) of FIG. 12). At this time, as illustrated in (c) of FIG. 12, an interval integral value S of a component of the targeted uneven streaks cycle 1 can be calculated without any influence of the noise. Note that, in (b) of FIG. 12, a low cycle (high frequency) component occurs besides the uneven streaks cycle.

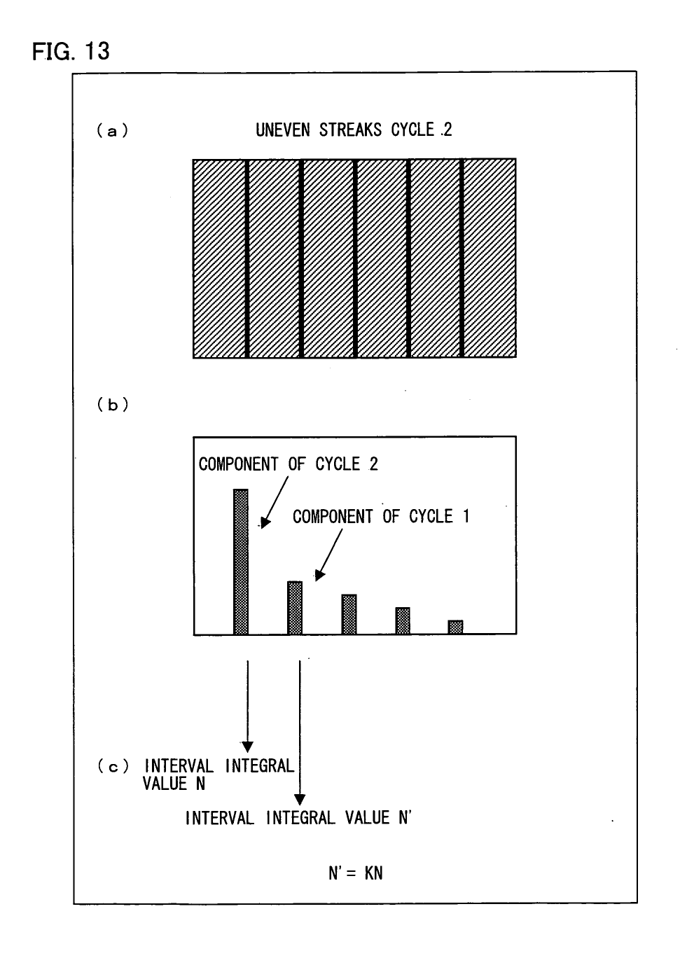

Next, with respect to an image of an uneven streaks cycle 2 illustrated in (a) of FIG. 13, spectrum estimation is carried out ((b) of FIG. 13). At this time, as illustrated in (c) of FIG. 13, not only an interval integral value N of a component of the targeted uneven streaks cycle 2 but also an interval integral value N′ in a cycle of the spectrum cycle 2 are calculated. At this time, this condition is represented by using a constant number K as follows: N′=KN.

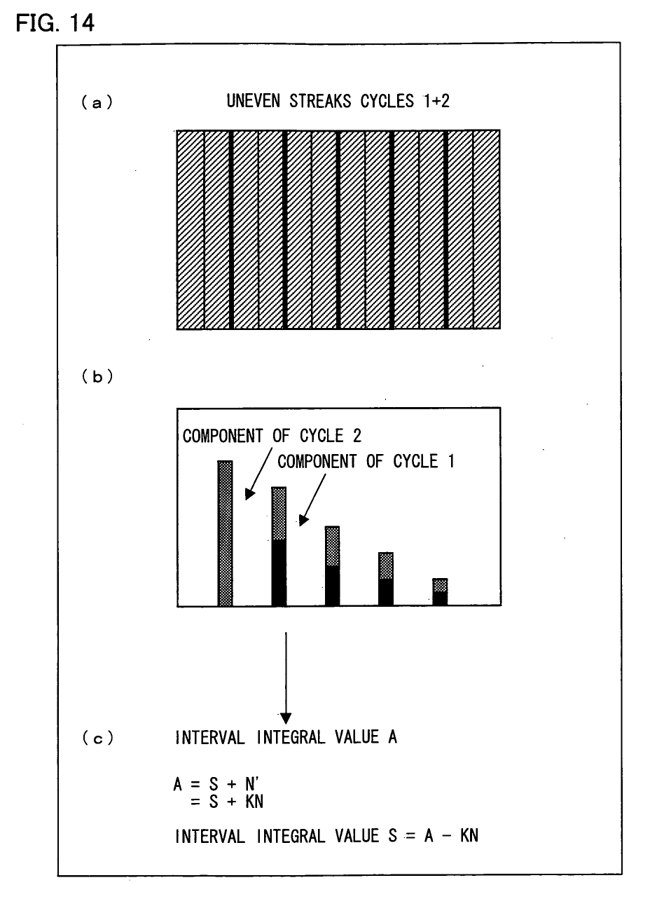

Next, let us consider a case of an image in which uneven streaks of cycle 1 and uneven streaks of cycle 2 exist in a mixed manner as illustrated in (a) of FIG. 14. With respect to this image, spectrum estimation is carried out ((b) of FIG. 14). At this time, as illustrated in (c) of FIG. 14, uneven streaks of cycle 1 are regarded as evaluation target uneven streaks, and uneven streaks of cycle 2 are regarded as noise components. When an interval integral value A of the cycle 1 component is calculated in accordance with the spectrum distribution, an interval integral value S of the cycle 1 and a low frequency component N′ of an interval integral value of uneven streaks of cycle 2 are included therein, so that this condition is represented by the following expression (5). Thus, the interval integral value S of the uneven streaks of cycle 1 is calculated, so that it is possible to calculate an interval integral value, from which a noise has been removed, in accordance with the following expression (6).

A=S+N′ (5)

S=A−KN (6)

As described above, it is general that, in the inkjet process, a cycle of uneven streaks varies depending on an occurrence cause of uneven streaks.

Thus, if it is possible to find out not only whether the uneven streaks are cyclic or not but also a cycle thereof, it is possible to find out an occurrence cause of uneven streaks, thereby making use of the cause in the manufacturing step of the color filter as the feedback.

In this case, the evaluation result includes not only unevenness cycle information indicative of whether uneven streaks are cyclic or not but also information for specifying the occurrence cause of uneven streaks, e.g., the aforementioned evaluation value (appearance intensity, appearance direction) of the specific cycle uneven streaks.

The following describes an example where unevenness cycle information of the color filter on the color filter substrate 330 is used as the feedback in the manufacturing step (production step) of the color filter substrate 330.

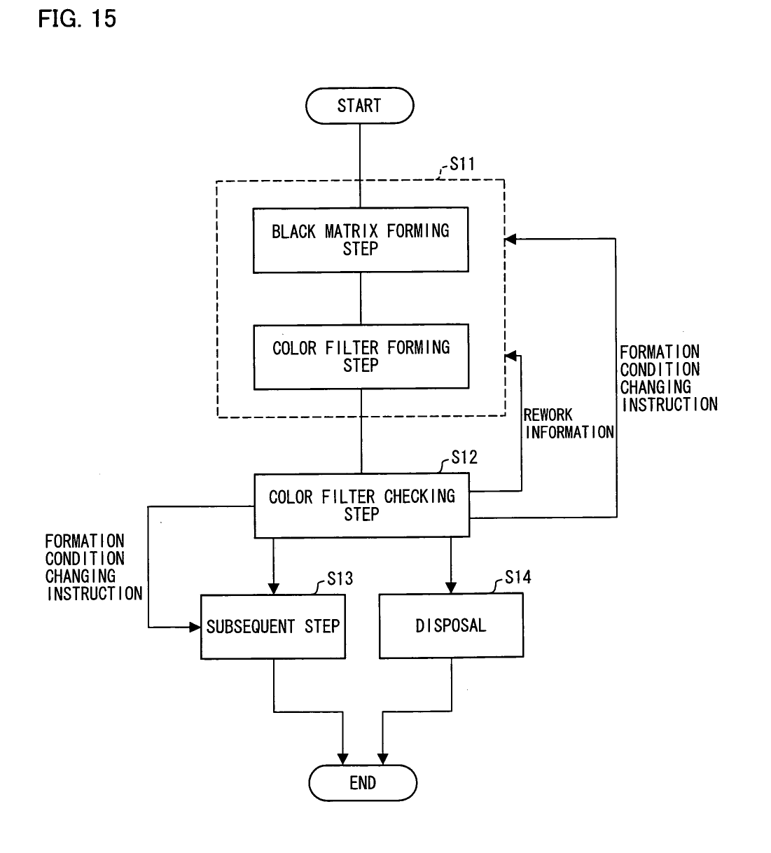

Note that, in the following description, a step of executing the aforementioned method for evaluating uneven streaks on the color filter (hereinafter, the step is referred to as “uneven streaks evaluation step”) is included in a series of steps in manufacturing the color filter substrate 330. For example, in the manufacturing steps (S11 to S14) of the color filter substrate illustrated in FIG. 15, the uneven streaks evaluation step is included in a step S12, i.e., a color filter checking step. Further, in view of the color filter checking step S12, a step S11 is a previous step and a step S13 is a subsequent step.

As illustrated in FIG. 15, the step S11 serving as the previous step includes a black matrix forming step and a color filter producing step.

In the black matrix forming step, a negative type acrylic photosensitive resin liquid in which carbon fine particles have been dispersed by spin coating is applied to a glass substrate, and then the resultant glass substrate is dried, thereby forming a black photosensitive resin layer. Subsequently, the black photosensitive resin layer is exposed via a photomask, and then development is carried out, thereby forming a black matrix (BM). For example, a black matrix 210 is formed on the glass substrate 220 as illustrated in FIG. 3. At this time, the black matrix 210 is formed so that there is formed an opening used in the color filter forming step serving as the subsequent step, i.e., an opening (corresponding to each color filter) which allows ink ejected from each nozzle 240 of the head unit 230 to be landed.

As described above, in the color filter forming step, the head unit 230 moves in a scanning direction (outward of the paper or inward of the paper of FIG. 3) with respect to the glass substrate 220 having the black matrix 210 thereon, so that the inkjet nozzles 240 eject liquid materials sequentially in the scanning direction onto the glass substrate 220 so that the liquid materials are respectively landed onto exposed parts of the glass substrate 220, thereby forming the color filter on the glass substrate 220. Note that, the black matrix 210 may be formed by inkjet, roller transfer, or a similar method. Further, a surface treatment may be carried out as necessary.

After completing the previous step of the step S11, the color filter checking step is carried out (step S12). In the color filter checking step, unevenness cycle information of the color filter is detected, and quality of the color filter is determined in accordance with the detection result.

Herein, the unevenness cycle information includes not only information indicative of whether uneven streaks are cyclic or not, information for specifying an occurrence cause of uneven streaks, but also an uneven streaks evaluation value indicative of uneven streaks appearance tendency such as a range, an intensity, and a direction of the uneven streaks and the like.

For example, in a device for manufacturing a color filter (color filter manufacturing device), if the uneven streaks information obtained by the color filter checking step includes information indicating that the uneven streaks are cyclic, information included in the unevenness information is compared with check reference information which has been prepared and stored in advance, thereby changing steps carried out with respect to the check target color filter (including the checking step and subsequent steps) in accordance with the comparison result. Note that, the check reference information may be registered into the aforementioned determination reference database, or may be registered into other database. In this manner, the check reference information may be registered in any database as long as the color filter manufacturing device can read information from the database as necessary.

The phrase “changing steps carried out with respect to the color filter” means the following state: For example, a color filter substrate having thereon a color filter whose spectrum value included in its unevenness cycle information is determined as being not less than a first predetermined value included in the check reference information is disposed of in accordance with check target step changing information which has bee prepared and stored in advance, and a color filter substrate having thereon a color filter whose spectrum value is determined as being less than the first predetermined value and not less than a second predetermined value is transported to a rework step. Note that, a color filter substrate having thereon a color filter whose spectrum value included in its unevenness cycle information is determined as being less than the second predetermined value is determined as a favorable product and is transported to a manufacturing step subsequently carried out after the checking step.

The color filter transported to the rework step is a color filter which is determined as being recoverable, and the color filter is transported to the rework step as well as rework information including positional information of an abnormal portion which information is obtained in the color filter checking step, and is subjected to a recovering process in the rework step, and then is transported to the checking step again so as to be checked. Note that, the rework step is included in the black matrix forming step or the color filter forming step of the step S11 of the manufacturing steps of the color filter substrate. The rework step is carried out in case of recovering only the abnormal portion and in case of entirely recovering the color filter substrate. Also, the rework step is carried out in case of recovering only the color filter and in case of recovering the black matrix and the color filter and a similar case.

Further, in the color filter checking step of the step S12, a spectrum value or the like at the time of determination of disposal or transportation to the rework step is used in the previous step S11 as the feedback. In case of using the spectrum value or the like in the color filter forming step as the feedback, formation conditions in the color filter forming step (e.g., adjustment of an amount of ink to be ejected, a moving rate of the head unit, and the like) are changed in accordance with the feedback spectrum value and the aforementioned determination reference database, thereby forming the color filter. Further, in case where it is determined that unevenness caused by an inappropriate width of the black matrix occur in the color filter checking step of the step S12, there is given an instruction to change black matrix formation conditions (adjustment of a photomask formation position for forming the black matrix and a similar condition) in the black matrix forming step. Further, in the black matrix forming step, the formation conditions are changed in accordance with the instruction, thereby forming the black matrix. Note that, change of the formation conditions in accordance with the spectrum value or the determination reference database etc. may be determined in steps before the formation, or it may be so arranged that the change is determined in steps around the color filter checking step and an instruction to change the formation conditions is transmitted to the previous step.

The color filter substrate including the color filter which has been checked in the foregoing manner and has been determined as being free from any problem is transported to the next step (step S13). Note that, it may be so arranged that: in case where the color filter is barely free from problem though the color filter is determined as being free from any problem, there is instructed to change the formation conditions so that the next step is carried out under the formation conditions based on the checking result of the color filter.

In the step S13, a counter electrode made of a transparent electrode such as ITO is formed by sputtering, and then a pillar spacer (not shown) for defining a cell gap of the liquid crystal panel for example is formed by applying an acrylic photosensitive resin liquid and carrying out exposure, development, and curing with a photomask.

In the foregoing manner, the color filter substrate 330 is formed.

As descried above, based on the unevenness cycle information which is the checking result obtained in the color filter checking step, the color filter having been checked can be processed in accordance with the checking result, so that it is possible to improve the yield of the resultant color filter.

Moreover, even in case where uneven streaks are cyclic, whether the color filter is recoverable or not is determined in accordance with an appearance intensity (spectrum value) of the uneven streaks, so that color filters each of which has cyclic uneven streaks are not entirely regarded as being improper, and out of the color filters each of which has cyclic uneven streaks, only color filters each of which has unrecoverable uneven streaks are determined as being improper and are then disposed of. This makes it possible to prevent color filters from being excessively disposed of, thereby improving the yield of the color filter and reducing the manufacturing cost.

As a result, it is possible to reduce the total time taken to manufacture the color filter.

The processes of the color filter serving as a check target work (evaluation target) may be changed with respect to only a single color filter, or may be changed with respect to all color filters belonging to the same lot, or may be changed with respect to all color filters whose types are identical to each other.

With respect to a color filter determined as being improper, a predetermined part of the color filter or an abnormal part of the color filter may be marked or be in a similar state.

In this case, the color filter determined as being improper is not disposed of in the forming step and is used so that the operator specifies the occurrence cause of the improper product.

Further, it may be so arranged that check-out values obtained in the checking steps of plural color filters (or plural parts of a color filter) are stored in a check-out value database (provided on the checking device for example), and the forming steps and the formation conditions are changed in case where a color filter is under conditions corresponding to conditions indicated by check reference information preset in the determination reference database.

For example, the number of sequential color filters each of which has a spectrum value included in its unevenness cycle information is equal to or larger than the reference value (the first predetermined value or the second predetermined value) or the number of times such color filter occurs is counted, and when the counted number of sequential color filters exceeds a predetermined number of color filters or the counted number of times such color filter occurs, the checking result is used as the feedback in the forming step which is previous to the step causing the improperness in accordance with the forming step changing information obtained by changing the forming step on the basis of the checking result.

Examples of change of the production method are as follows: Production conditions of the production device are changed; Check of necessity of maintenance of the production device is started; The production device is stopped; A part causing the improperness is cleaned or replaced by a new part.

Further, it may be so arranged that the check-out value is transmitted to a production step which is subsequent to the checking step so as to change the production method.

For example, with respect to a color filter belonging to a lot having a predetermined number or more of color filters each of which has a check-out value (spectrum value) equal to or larger than a certain reference, production conditions in the next production step may be changed in accordance with the production step changing information so that a large check-out value is lowered, for example, a final luminance value is within a final check reference range.

Note that, the present embodiment uses Fourier transform for analyzing a cycle as an example of the cycle analysis process, but the cycle analysis process is not particularly limited to this as long as it is possible to check whether uneven streaks are cyclic or not.

Further, in the present embodiment, light is emitted to a surface of the display member so as to carry out analysis in accordance with reflected light distribution, but the analysis may be carried out in accordance with transmitted light distribution.

Also in case of utilizing the transmitted light, the same image processing procedure as the image processing procedure utilizing the reflected light can be adopted.

For example, it may be so arranged that: light is emitted to a rear surface of the display member (color filter) so as to carry out the cycle analysis in accordance with a transmitted light distribution obtained by causing light to be transmitted through a front surface, i.e., a color filter formation surface.

In this case, the illumination device is provided in a color filter non-formation surface, and the camera is provided on the color filter formation surface (front side of the display member). As to an angle at which the camera is provided, it is preferable to set the angle so that it is easy to observe unevenness occurring on the color filter formation surface. For example, as in the case of the reflected light, unlike the case of straight transmitted light, it is preferable that an angle of light emitted to the rear surface of the substrate is different from an angle of the transmitted light with respect to the substrate. Specifically, it may be so arranged that: the illumination device is provided in a normal line direction of the substrate, and the camera is provided at an angle inclined from the normal line of the substrate, or the illumination device is provided at an angle inclined from the normal line of the substrate, and the camera is provided in the normal line of the substrate or at an angle inclined from a direction of the straight transmitted light.

In the present embodiment, the cycle analysis process is carried out with respect to the data having been subjected to the one-dimensional projection process, but a filtering process (morphology process) may be carried out before carrying out the cycle analysis process.

Note that, the filtering process refers to a process for extracting or suppressing an amplitude of a certain cycle width of information obtained by carrying out the one-dimensional projection with respect to light distribution information (luminance distribution information).

The present invention is not limited to the description of the embodiments above, but may be altered by a skilled person within the scope of the claims. An embodiment based on a proper combination of technical means disclosed in different embodiments is encompassed in the technical scope of the present invention.

Lastly, the respective blocks of the evaluation device 100, particularly, the one-dimensional projection processing section 121, the power spectrum calculation section 122, the integration processing section 123, and the noise component removing section 124 may be constituted by hardware logic, or may be realized by software with use of a processor such as a CPU.

That is, the evaluation device 100 includes: a CPU (central processing unit) for carrying out a command of a control program for realizing the functions; a ROM (read only memory) in which the program is stored; a RAM (random access memory) for developing the program; a storage device (storage medium), such as a memory, in which the program and various kinds of data are stored; and the like. Further, the object of the present invention can be achieved as follows: a storage medium for computer-readably storing a program code (an execute form program, intermediate code program, or source program) of the control program which is software for implementing the aforementioned functions is provided to the evaluation device 100, and a computer (or CPU and MPU) provided on the evaluation device 100 reads out the program code stored in the storage medium so as to implement the program, thereby achieving the object of the present invention.

Examples of the storage medium which satisfies these conditions include: tapes, such as magnetic tape and cassette tape; disks including magnetic disks, such as floppy disks (registered trademark) and hard disk, and optical disks, such as CD-ROMs, magnetic optical disks (MOs), mini disks (MDs), digital video disks (DVDs), and CD-Rs; cards, such as IC card (including memory cards) and optical cards; and semiconductor memories, such as mask ROMs, EPROMs, EEPROMs, and flash ROMs.

Further, it may be so arranged that: the evaluation device 100 is made connectable to communication networks, and the program code is supplied via the communication networks. The communication networks are not limited to a specific means. Specific examples of the communication network include Internet, intranet, extranet, LAN, ISDN, VAN, a CATV communication network, a virtual private network, a telephone line network, a mobile communication network, a satellite communication network, and the like. Further, a transmission medium constituting the communication network is not particularly limited. Specifically, it is possible to use a wired line such as a line in compliance with IEEE1394 standard, a USB line, a power line, a cable TV line, a telephone line, an ADSL line, and the like, as the transmission medium. Further, it is possible to use (i) a wireless line utilizing an infrared ray used in IrDA and a remote controller, (ii) a wireless line which is in compliance with Bluetooth standard (registered trademark) or IEEE802.11 wireless standard, and (iii) a wireless line utilizing HDR, a mobile phone network, a satellite line, a ground wave digital network, and the like, as the transmission medium. Note that, the present invention can be realized by a computer data signal (data signal sequence) which is realized by electronic transmission of the program code and which is embedded in a carrier wave.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

What is claimed is:

1. An uneven streaks evaluation device, comprising evaluation data generation means for generating evaluation data, serving as an index for evaluating cyclic uneven streaks which occur on an evaluation target surface of a display member, in accordance with image data obtained by imaging the evaluation target surface to which light is emitted, wherein
the evaluation data generation means includes:
one-dimensional projection processing means for carrying out a one-dimensional projection process with respect to light distribution included in the image data;
power spectrum calculation means for calculating a power spectrum in accordance with the light distribution having been subjected to the one-dimensional projection process carried out by the one-dimensional projection processing means;
integration means for calculating an interval integral value of a preset cycle in accordance with the power spectrum calculated by the power spectrum calculation means; and
noise component removing means for removing a noise component included in the interval integral value calculated by the integration means.

2. The uneven streaks evaluation device as set forth in claim 1, further comprising area dividing means for dividing the image data into a plurality of areas, wherein
the evaluation data generation means generates evaluation data for the image data so that the evaluation data corresponds to each of the areas obtained through division carried out by the area dividing means.

3. The uneven streaks evaluation device as set forth in claim 2, wherein the area dividing means divides the image data into areas so as to correspond to a preset range of uneven streaks.

4. The uneven streaks evaluation device as set forth in claim 2, wherein the area dividing means causes the areas to overlap with each other so that a range of uneven streaks occurring at a specific cycle is positioned in the same area in dividing the image data into areas.

5. The uneven streaks evaluation device as set forth in claim 2, further comprising evaluation value calculation means for calculating an evaluation value, which is indicative of an appearance position and an appearance intensity of uneven streaks occurring at a specific cycle in the image data, in accordance with the evaluation data, wherein
the evaluation value calculation means calculates the evaluation value in accordance with the evaluation data generated by the evaluation data generation means so that the evaluation data corresponds to each of the areas.

6. The uneven streaks evaluation device as set forth in claim 5, wherein
the evaluation value calculation means calculates evaluation data in the same direction as a direction in which uneven streaks occur is extracted from the evaluation data having been generated, and an evaluation value of the uneven streaks is calculated in accordance with the evaluation data having been extracted.

7. The uneven streaks evaluation device as set forth in claim 6, wherein
the evaluation value calculation means calculates, as an evaluation value of uneven streaks, any one of (i) an arithmetic average value of the evaluation data having been extracted, (ii) a trim average value of the evaluation data having been extracted, (iii) a median value of the evaluation data having been extracted, and (iv) an rms (root mean square) value of the evaluation data having been extracted.

8. The uneven streaks evaluation device as set forth in claim 1, wherein the one-dimensional projection processing means carries out the one-dimensional projection process with respect to the light distribution information so that a projection direction is the same as the direction in which uneven streaks occur.

9. The uneven streaks evaluation device as set forth in claim 1, wherein a range of the interval integral value calculated by the integration means includes a cycle of uneven streaks to be evaluated.

10. The uneven streaks evaluation device as set forth in claim 1, wherein a range of the interval integral value calculated by the integration means includes a cycle having a certain intensity.

11. The uneven streaks evaluation device as set forth in claim 1, wherein the integration means calculates a power spectrum density in accordance with the power spectrum and carries out interval integration with respect to a result of the calculation at a preset cycle so as to calculate the interval integral value.

12. The uneven streaks evaluation device as set forth in claim 1, wherein the integration means calculates a power spectrum density in accordance with the power spectrum and calculates a square root of a value, obtained by carrying out interval integration with respect to a result of that calculation at a preset cycle, so as to calculate the interval integral value.

13. The uneven streaks evaluation device as set forth in claim 1, wherein the noise component removed by the noise component removing means is a cycle component different from a cycle of uneven streaks to be evaluated.

14. The uneven streaks evaluation device as set forth in claim 13, wherein the noise component includes a cycle component having a certain intensity.

15. The uneven streaks evaluation device as set forth in claim 1, further comprising evaluation value calculation means for calculating an evaluation value, which is indicative of an appearance position and an appearance intensity of uneven streaks occurring at a specific cycle in the image data, in accordance with the evaluation data, wherein
the evaluation data generation means generates evaluation data sets respectively in accordance with a plurality of image data sets respectively obtained by imaging the evaluation target surface of the same display member from different directions, and
the evaluation calculation means extracts, from the evaluation data having been generated by the evaluation data generation means, evaluation data generated in accordance with an image data set obtained from a direction which allows less influence of the noise component, and calculates the evaluation value in accordance with the evaluation data having been extracted.

16. The uneven streaks evaluation device as set forth in claim 15, wherein the directions in which the image data sets are obtained at least include: an oblique direction in which a characteristic of uneven streaks are capable of being observed; and a direction opposite to the oblique direction.

17. The uneven streaks evaluation device as set forth in claim 1, wherein the display member is a color filter.

18. A method for evaluating cyclic uneven streaks occurring on an evaluation target surface of a display member, in accordance with image data obtained by imaging the evaluation target surface to which light is emitted,
said method comprising:
a first step of carrying out a one-dimensional projection process with respect to light distribution information included in the image data so that a projection direction is a direction including a vector of a direction in which uneven streaks occur;
a second step of calculating a power spectrum in accordance with the light distribution having been subjected to the one-dimensional projection process in the first step;
a third step of calculating an interval integral value of a preset cycle in accordance with the power spectrum calculated in the second step; and
a fourth step of removing a noise component included in the interval integral value calculated in the third step.

19. A computer-readable storage medium, storing therein a control program which causes a computer to function as means of an uneven streaks evaluation device which comprises evaluation data generation means for generating evaluation data, serving as an index for evaluating cyclic uneven streaks which occur on an evaluation target surface of a display member, in accordance with image data obtained by imaging the evaluation target surface to which light is emitted, wherein the evaluation data generation means includes: one-dimensional projection processing means for carrying out a one-dimensional projection process with respect to light distribution included in the image data; power spectrum calculation means for calculating a power spectrum in accordance with the light distribution having been subjected to the one-dimensional projection process carried out by the one-dimensional projection processing means; integration means for calculating an interval integral value of a preset cycle in accordance with the power spectrum calculated by the power spectrum calculation means; and noise component removing means for removing a noise component included in the interval integral value calculated by the integration means.

20. A method for manufacturing a color filter by using a color filter manufacturing device,
said method comprising an uneven streaks evaluation step of carrying out a method for evaluating cyclic uneven streaks occurring on an evaluation target surface of the color filter, in accordance with image data obtained by imaging the evaluation target surface to which light is emitted, this method including: a first step of carrying out a one-dimensional projection process with respect to light distribution information included in the image data so that a projection direction is a direction including a vector of a direction in which uneven streaks occur; a second step of calculating a power spectrum in accordance with the light distribution having been subjected to the one-dimensional projection process in the first step; a third step of calculating an interval integral value of a preset cycle in accordance with the power spectrum calculated in the second step; and a fourth step of removing a noise component included in the interval integral value calculated in the third step, wherein
the evaluation value which has been obtained in the uneven streaks evaluation step and is indicative of an appearance tendency of unevenness streaks occurrence is outputted to the color filter manufacturing device as feedback information.
